(19) United States
(12) Patent Application Publication
(10) Pub. No.: US 2026/0191052 A1
(43) Pub. Date: Jul. 2, 2026

(54) SUBSTRATE STRUCTURE

(71) Applicant: Unimicron Technology Corp., Taoyuan City (TW)

(72) Inventors: Tzyy-Jang Tseng, Taoyuan City (TW); Chin-Sheng Wang, Taoyuan City (TW); Ra-Min Tain, Hsinchu County (TW); Guang-Hwa Ma, Hsinchu City (TW)

(73) Assignee: Unimicron Technology Corp., Taoyuan City (TW)

(21) Appl. No.: 19/183,912

(22) Filed: Apr. 20, 2025

Related U.S. Application Data
(60) Provisional application No. 63/739,681, filed on Dec. 30, 2024.

(30) Foreign Application Priority Data
Mar. 4, 2025 (TW) 114107984

(51) Int. Cl. H01L 23/498; H01L 23/00

(52) U.S. Cl. CPC H10W 70/65; H10W 42/121

(57) ABSTRACT

A substrate structure includes a coreless substrate and a first build-up structure layer. The coreless substrate includes at least one first dielectric layer and at least one first conductive pattern layer. The first build-up structure layer is disposed on the coreless substrate and includes at least one second dielectric layer and at least one second conductive pattern layer. A coefficient of thermal expansion of the at least one second dielectric layer is less than a coefficient of thermal expansion of the at least one first dielectric layer. The at least one second conductive pattern layer is electrically connected to the at least one first conductive pattern layer.

### CROSS-REFERENCE TO RELATED APPLICATION

This application claims the priority benefit of U.S. Provisional Application No. 63/739,681, filed on Dec. 30, 2024 and Taiwan Application No. 114107984, filed on Mar. 4, 2025. The entirety of each of the above-mentioned patent applications is hereby incorporated by reference herein and made a part of this specification.

### BACKGROUND

### Technical Field

The disclosure relates to a substrate structure, and more particularly to a substrate structure with improved structural reliability.

### Description of Related Art

The high-end integrated circuit (IC) carrier and circuit board are becoming larger and thicker with lower manufacturing yield and more severe board warpage. In order to solve the issue of board warpage, an inner core board needs to be thickened to increase supporting strength. However, such a manner causes the diameter and the spacing of conductive through holes to become larger, resulting in a low density of the conductive through holes, which is not conducive to the application of a high-end product. Furthermore, if a glass substrate is adopted as a core layer, the thickness of the core board is usually greater than 0.5 mm, and the diameter of the conductive through hole is less than 0.1 mm, resulting in a low electroplating hole filling yield. In addition, the coefficient of thermal expansion of a build-up structure on the core layer is greater than the coefficient of thermal expansion of the core layer, so a tensile stress is generated after a heating process (for example, curing), which may easily cause the core layer made of the glass material to tear in the middle, thereby reducing the structural reliability of the product.

### SUMMARY

The disclosure provides a substrate structure with improved structural reliability.

A substrate structure of the disclosure includes a coreless substrate and a first build-up structure layer. The coreless substrate includes at least one first dielectric layer and at least one first conductive pattern layer. The first build-up structure layer is disposed on the coreless substrate and includes at least one second dielectric layer and at least one second conductive pattern layer. A coefficient of thermal expansion of the at least one second dielectric layer is less than a coefficient of thermal expansion of the at least one first dielectric layer. The at least one second conductive pattern layer is electrically connected to the at least one first conductive pattern layer.

In an embodiment of the disclosure, the substrate structure further includes a bonding layer and at least one conductive member. The bonding layer is disposed between the coreless substrate and the first build-up structure layer. The at least one conductive member is disposed in the bonding layer and electrically connects the at least one second conductive pattern layer and the at least one first conductive pattern layer.

In an embodiment of the disclosure, a material of the at least one conductive member includes conductive paste, metal paste, or nanowire.

In an embodiment of the disclosure, a material of the at least one first dielectric layer of the coreless substrate includes an organic material, an inorganic material, or a non-conductive composite material.

In an embodiment of the disclosure, a material of at least one second dielectric layer of the first build-up structure layer includes an organic material, an inorganic material, or a non-conductive composite material.

In an embodiment of the disclosure, a material of the at least one first dielectric layer of the coreless substrate and a material of the at least one second dielectric layer of the first build-up structure layer are the same.

In an embodiment of the disclosure, a material of the at least one first dielectric layer of the coreless substrate is different from a material of the at least one second dielectric layer of the first build-up structure layer.

In an embodiment of the disclosure, the substrate structure further includes a second build-up structure layer disposed on the coreless substrate and including at least one third dielectric layer and at least one third conductive pattern layer. The coreless substrate is located between the first build-up structure layer and the second build-up structure layer. A coefficient of thermal expansion of the at least one third dielectric layer is less than a coefficient of thermal expansion of the at least one first dielectric layer, and the at least one third conductive pattern layer is electrically connected to the at least one first conductive pattern layer.

In an embodiment of the disclosure, the coefficient of thermal expansion of the at least one third dielectric layer is different from the coefficient of thermal expansion of the at least one second dielectric layer.

In an embodiment of the disclosure, the at least one second dielectric layer of the first build-up structure layer includes an internal dielectric layer and at least two external dielectric layers. The internal dielectric layer is located between the at least two external dielectric layers, and a coefficient of thermal expansion of the internal dielectric layer is different from coefficients of thermal expansion of the at least two external dielectric layers.

Based on the above, in the substrate structure of the disclosure, since the coefficient of thermal expansion of the second dielectric layer of the first build-up structure layer is less than the coefficient of thermal expansion of the first dielectric layer without the core substrate, a compressive stress may be formed to suppress the warping of the substrate structure, so that the substrate structure of the disclosure can have improved structural reliability.

In order for the features and advantages of the disclosure to be more comprehensible, the following specific embodiments are described in detail in conjunction with the drawings.

### BRIEF DESCRIPTION OF THE DRAWINGS

FIG. 1 is a schematic cross-sectional view of a substrate structure according to an embodiment of the disclosure.

FIG. 2 is a schematic cross-sectional view of a substrate structure according to another embodiment of the disclosure.

FIG. 3 is a schematic cross-sectional view of a substrate structure according to another embodiment of the disclosure.

FIG. 4 is a schematic cross-sectional view of a substrate structure according to another embodiment of the disclosure.

### DESCRIPTION OF THE EMBODIMENTS

The embodiments of the disclosure may be understood in conjunction with the drawings, and the drawings of the disclosure are also considered as a part of the disclosure. It should be understood that the drawings of the disclosure are not drawn to scale, and in fact, sizes of elements may be arbitrarily enlarged or reduced in order to clearly illustrate the features of the disclosure.

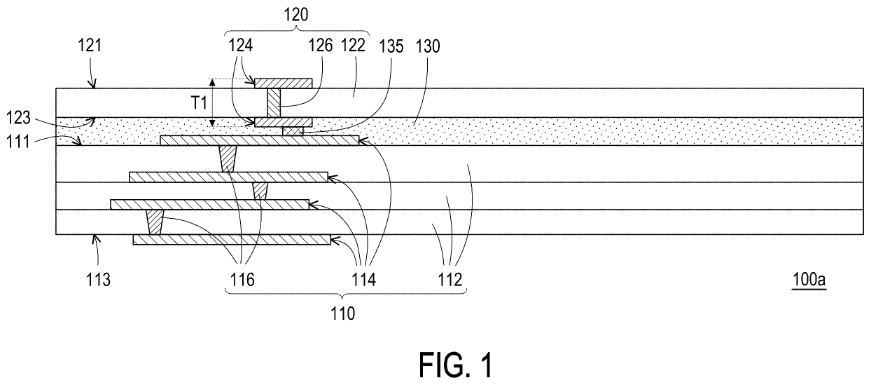

FIG. 1 is a schematic cross-sectional view of a substrate structure according to an embodiment of the disclosure. Please refer to FIG. 1. In the embodiment, a substrate structure 100a includes a coreless substrate 110 and a first build-up structure layer 120. The coreless substrate 110 includes at least one first dielectric layer (three first dielectric layers 112 are schematically shown) and at least one first conductive pattern layer (four first conductive pattern layers 114 are schematically shown). The first build-up structure layer 120 is disposed on the coreless substrate 110 and includes at least one second dielectric layer (one second dielectric layer 122 is schematically shown) and at least one second conductive pattern layer (two second conductive pattern layers 124 are schematically shown). The coefficient of thermal expansion of each second dielectric layer 122 is less than the coefficient of thermal expansion of each first dielectric layer 112. The second conductive pattern layer 124 is electrically connected to the first conductive pattern layer 114.

Specifically, in the embodiment, the coreless substrate 110 has a first surface 111 and a second surface 113 opposite to each other, wherein the first dielectric layer 112 and the first conductive pattern layer 114 are alternately stacked. In an embodiment, the outermost first conductive pattern layer 114 may be located on the first surface 111 and the second surface 113. In an embodiment, the outermost first conductive pattern layer 114 may be buried in the first surface 111 and the second surface 113. The material of the first dielectric layer 112 of the coreless substrate 110 is, for example, an organic material, an inorganic material, or a non-conductive composite material. In an embodiment, the organic material is, for example, a glass fiber resin (for example, FR4), a prepreg (PP), or an inorganic filler mixed in a resin (for example, an Ajinomoto build-up film (ABF)), but not limited thereto. In an embodiment, the inorganic material is, for example, glass, ceramic, or glass ceramic. In an embodiment, the first dielectric layers 112 may be made of the same material. In an embodiment, the first dielectric layers 112 may be made of at least two different materials. The coreless substrate 110 of the embodiment further includes a conductive hole 116. In an embodiment, the conductive hole 116 is, for example, a conductive blind hole, a conductive through hole, or a combination thereof and is disposed in the first dielectric layer 112 and electrically connects two adjacent first conductive pattern layers 114. In an embodiment, the first conductive pattern layer 114 is, for example, a trace, a pad, or a combination thereof. In an embodiment, the coreless substrate 110 may be a coreless substrate having multi-layer circuits.

Furthermore, please refer to FIG. 1 again. The first build-up structure layer 120 of the embodiment is disposed on the first surface 111 of the coreless substrate 110. The first build-up structure layer 120 has an outer surface 121 and an inner surface 123 opposite to each other, wherein the inner surface 123 is located between the outer surface 121 and the coreless substrate 110, and the second conductive pattern layer 124 is located on the outer surface 121 and the inner surface 123. In the embodiment, the first build-up structure layer 120 further includes a conductive hole 126, wherein the conductive hole 126 is, for example, a conductive through hole, penetrates the second dielectric layer 122, and is electrically connected to the second conductive pattern layer 124. The material of the second dielectric layer 122 of the first build-up structure layer 120 is, for example, an organic material, an inorganic material, or a non-conductive composite material. In an embodiment, the organic material is, for example, a glass fiber resin (for example, FR4), a prepreg (PP), or an inorganic filler mixed in a resin (for example, an Ajinomoto build-up film (ABF)), but not limited thereto. In an embodiment, the inorganic material is, for example, glass, ceramic, or glass ceramic.

In an embodiment, the material of the first dielectric layer 112 of the coreless substrate 110 and the material of the second dielectric layer 122 of the first build-up structure layer 120 are the same, such as an organic material. In an embodiment, the material of the first dielectric layer 112 of the coreless substrate 110 and the material of the second dielectric layer 122 of the first build-up structure layer 120 are the same, such as an inorganic material. In an embodiment, the material of the first dielectric layer 112 of the coreless substrate 110 is different from the material of the second dielectric layer 122 of the first build-up structure layer 120. In an embodiment, the material of the first dielectric layer 112 of the coreless substrate 110 is an organic material, and the material of the second dielectric layer 122 of the first build-up structure layer 120 is an inorganic material. In an embodiment, the material of the first dielectric layer 112 of the coreless substrate 110 is an inorganic material, and the material of the second dielectric layer 122 of the first build-up structure layer 120 is an organic material. In an embodiment, the first build-up structure layer 120 has a lower coefficient of thermal expansion and a higher Young's modulus than the coreless substrate 110. In an embodiment, when the second dielectric layer 122 of the first build-up structure layer 120 is made of a glass material, the outer surface 121 and the inner surface 123 are respectively a very flat surface suitable for manufacturing a high-density circuit (for example, an ultra-fine line redistribution circuit) or for assembly thereon. In an embodiment, the first build-up structure layer 120 may be regarded as an interposer, wherein a thickness T1 of the first build-up structure layer 120 is, for example, in a range of 50 μm to 800 μm.

In addition, please refer to FIG. 1 again. The substrate structure 100a of the embodiment further includes a bonding layer 130 and at least one conductive member (one conductive member 135 is schematically shown). The bonding layer 130 is disposed between the coreless substrate 110 and the first build-up structure layer 120, wherein the bonding layer 130 covers the first surface 111 of the coreless substrate 110, the first conductive pattern layer 114 located on the first surface 111, the inner surface 123 of the first build-up structure layer 120, and the second conductive pattern layer 124 located on the inner surface 123. The first build-up structure layer 120 is fixed onto the first surface 111 of the coreless substrate 110 through the bonding layer 130. The conductive member 135 is disposed in the bonding layer 130 and electrically connects the second conductive pattern layer 124 and the first conductive pattern layer 114. In an embodiment, the material of the conductive member 135 is, for example, conductive paste (for example, transient liquid phase sintering (TLPS)), metal paste (for example, copper paste or silver paste), or nanowire, but not limited thereto. In an embodiment, when the conductive member 135, the second conductive pattern layer 124, and the first conductive pattern layer 114 are all made of copper, copper and copper may also be directly bonded. In an embodiment, the material of the bonding layer 130 is, for example, polyimide (PI), an Ajinomoto build-up film (ABF), bismaleimide-triazine (BT), or other polymers. In an embodiment, the thickness of the bonding layer 130 is, for example, 8 μm to 100 μm. In an embodiment, the bonding layer 130 has a low modulus and may serve as a stress buffer layer.

In short, since the coefficient of thermal expansion of the second dielectric layer 122 of the first build-up structure layer 120 is less than the coefficient of thermal expansion of the first dielectric layer 112 of the coreless substrate 110, a compressive stress may be formed to suppress the warping of the substrate structure 100a, so that the substrate structure 100a of the embodiment can have improved structural reliability. In addition, since the coreless substrate 110 and the first build-up structure layer 120 are bonded through the bonding layer 130, the coreless substrate 110 and the first build-up structure layer 120 may be separately wired before bonding, which may increase the wiring density of the substrate structure 100a.

Other embodiments are listed below for illustration. It should be noted that the following embodiments continue to use the reference numerals and some content of the foregoing embodiment, wherein the same reference numerals are adopted to represent the same or similar elements, and the description of the same technical content is omitted. Reference may be made to the foregoing embodiment for the description of the omitted part, which will not be repeated in the following embodiments.

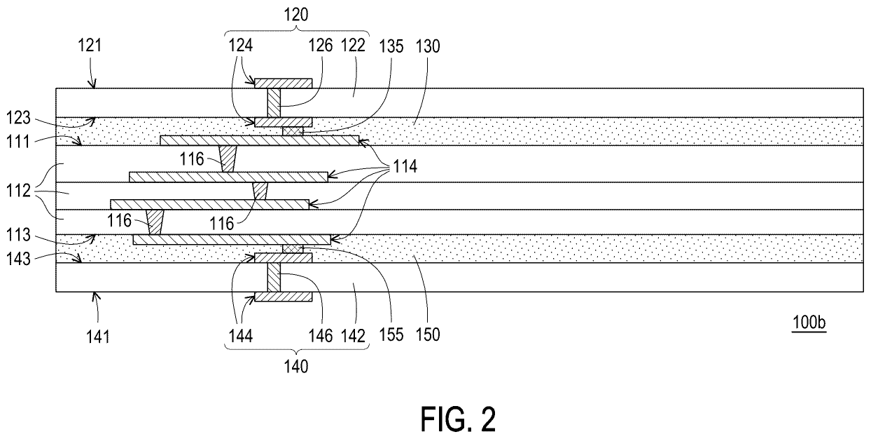

FIG. 2 is a schematic cross-sectional view of a substrate structure according to another embodiment of the disclosure. Please refer to FIG. 1 and FIG. 2 simultaneously. A substrate structure 100b of the embodiment is similar to the substrate structure 100a, but the main difference between the two is that in the embodiment, the substrate structure 100b further includes a second build-up structure layer 140 disposed on the coreless substrate 110 and including at least one third dielectric layer 142 (one third dielectric layer 142 is schematically shown) and at least one third conductive pattern layer 144 (two third conductive pattern layers 144 are schematically shown). The coreless substrate 110 is located between the first build-up structure layer 120 and the second build-up structure layer 140. The coefficient of thermal expansion of the third dielectric layer 142 is less than the coefficient of thermal expansion of the first dielectric layer 112, and the third conductive pattern layer 144 is electrically connected to the first conductive pattern layer 114.

In detail, the second build-up structure layer 140 of the embodiment is located on the second surface 113 of the coreless substrate 110. The second build-up structure layer 140 has an outer surface 141 and an inner surface 143 opposite to each other, wherein the inner surface 143 is located between the outer surface 141 and the coreless substrate 110, and the third conductive pattern layer 144 is located on the outer surface 141 and the inner surface 143. In the embodiment, the second build-up structure layer 140 further includes a conductive hole 146, wherein the conductive hole 146 is, for example, a conductive through hole, penetrates the third dielectric layer 142, and is electrically connected to the third conductive pattern layer 144. The material of the third dielectric layer 142 of the second build-up structure layer 140 is, for example, an organic material, an inorganic material, or a non-conductive composite material. In an embodiment, the organic material is, for example, a glass fiber resin (for example, FR4), a prepreg (PP), or an inorganic filler mixed in a resin (for example, an Ajinomoto build-up film (ABF)), but not limited thereto. In an embodiment, the inorganic material is, for example, glass, ceramic, or glass ceramic.

In an embodiment, the material of the first dielectric layer 112 of the coreless substrate 110 and the material of the third dielectric layer 142 of the second build-up structure layer 140 are the same, such as an organic material. In an embodiment, the material of the first dielectric layer 112 of the coreless substrate 110 and the material of the third dielectric layer 142 of the second build-up structure layer 140 are the same, such as an inorganic material. In an embodiment, the material of the first dielectric layer 112 of the coreless substrate 110 is different from the material of the third dielectric layer 142 of the second build-up structure layer 140. In an embodiment, the material of the first dielectric layer 112 of the coreless substrate 110 is an organic material, and the material of the third dielectric layer 142 of the second build-up structure layer 140 is an inorganic material. In an embodiment, the material of the first dielectric layer 112 of the coreless substrate 110 is an inorganic material, and the material of the third dielectric layer 142 of the second build-up structure layer 140 is an organic material. In an embodiment, the second build-up structure layer 140 has a lower coefficient of thermal expansion and a higher Young's modulus than the coreless substrate 110.

In an embodiment, the coefficient of thermal expansion of the third dielectric layer 142 of the second build-up structure layer 140 is different from the coefficient of thermal expansion of the second dielectric layer 122 of the first build-up structure layer 120 to obtain improved matching of coefficients of thermal expansion, which can improve the structural reliability of the substrate structure 100b. In an embodiment, the coefficient of thermal expansion of the third dielectric layer 142 of the second build-up structure layer 140 is higher than the coefficient of thermal expansion of the second dielectric layer 122 of the first build-up structure layer 120. In an embodiment, the second dielectric layer 122 of the first build-up structure layer 120 may have a lower coefficient of thermal expansion, such as between 2 ppm/° C. and 8 ppm/° C., which may match a silicon chip subsequently disposed thereon, and the third dielectric layer 142 of the second build-up structure layer 140 may have a higher coefficient of thermal expansion, such as between 3 ppm/° C. and 12 ppm/° C., which may match a printed circuit board subsequently disposed thereon.

In an embodiment, the material of the second dielectric layer 122 of the first build-up structure layer 120, the material of the first dielectric layer 112 of the coreless substrate 110, and the material of the third dielectric layer 142 of the second build-up structure layer 140 may be a combination of glass, an organic material, and glass (GOG) in sequence. In an embodiment, the material of the second dielectric layer 122 of the first build-up structure layer 120, the material of the first dielectric layer 112 of the coreless substrate 110, and the material of the third dielectric layer 142 of the second build-up structure layer 140 may be a combination of ceramic, an organic material, and ceramic (COC) in sequence. In an embodiment, the material of the second dielectric layer 122 of the first build-up structure layer 120, the material of the first dielectric layer 112 of the coreless substrate 110, and the material of the third dielectric layer 142 of the second build-up structure layer 140 may be a combination of ceramic, an organic material, and glass (COG) in sequence. In an embodiment, the material of the second dielectric layer 122 of the first build-up structure layer 120, the material of the first dielectric layer 112 of the coreless substrate 110, and the material of the third dielectric layer 142 of the second build-up structure layer 140 may be a combination of glass, an organic material, and ceramic (GOC) in sequence. In an embodiment, the substrate structure 100b may be regarded as a hybrid core structure.

It is worth mentioning that in a structure where two pieces of glass (for example, the second dielectric layer 122 of the first build-up structure layer 120 and the third dielectric layer 142 of the second build-up structure layer 140) are coated on two sides of an organic material (for example, the first dielectric layer 112 of the coreless substrate 110), the thickness of the organic material may be effectively reduced and rigidity may be improved. Furthermore, since the thickness of the organic material may be reduced, smaller through holes may be used, the spacing may be reduced, and the density of the conductive through holes may be correspondingly increased.

In addition, please refer to FIG. 2 again. The substrate structure 100b of the embodiment further includes a bonding layer 150 and at least one conductive member (one conductive member 155 is schematically shown). The bonding layer 150 is disposed between the coreless substrate 110 and the second build-up structure layer 140, wherein the bonding layer 150 covers the second surface 113 of the coreless substrate 110, the first conductive pattern layer 114 located on the second surface 113, the inner surface 143 of the second build-up structure layer 140, and the third conductive pattern layer 144 located on the inner surface 143. The second build-up structure layer 140 is fixed onto the second surface 113 of the coreless substrate 110 through the bonding layer 150. The conductive member 155 is disposed in the bonding layer 150 and electrically connects the third conductive pattern layer 144 and the first conductive pattern layer 114. In an embodiment, the material of the conductive member 155 is, for example, conductive paste (for example, TLPS), metal paste (for example, copper paste or silver paste), or nanowire, but not limited thereto. In an embodiment, when the conductive member 155, the third conductive pattern layer 144, and the first conductive pattern layer 114 are all made of copper, copper and copper may also be directly bonded. In an embodiment, the material of the bonding layer 150 is, for example, polyimide (PI), an Ajinomoto build-up film (ABF), bismaleimide-triazine (BT), or other polymers. In an embodiment, the thickness of the bonding layer 150 is, for example, 8 μm to 100 μm. In an embodiment, the bonding layer 150 has a low modulus and may serve as a stress buffer layer.

In short, the first build-up structure layer 120 and the second build-up structure layer 140 are respectively disposed on two sides of the coreless substrate 110, wherein the coefficient of thermal expansion of the second dielectric layer 122 of the first build-up structure layer 120 and the coefficient of thermal expansion of the third dielectric layer 142 of the second build-up structure layer 140 are both less than the coefficient of thermal expansion of the first dielectric layer 112 of the coreless substrate 110. Therefore, a compressive stress may be formed to suppress the warping of the substrate structure 100b, which may improve the rigidity and flatness of the substrate structure 100b, so that the substrate structure 100b of the embodiment can have improved structural reliability. In addition, since the coreless substrate 110 and the first build-up structure layer 120 are bonded through the bonding layer 130, and the coreless substrate 110 and the second build-up structure layer 140 are bonded through the bonding layer 150, the coreless substrate 110, the first build-up structure layer 120, and the second build-up structure layer 140 may be separately wired before bonding, which may increase the wiring density of the substrate structure 100b.

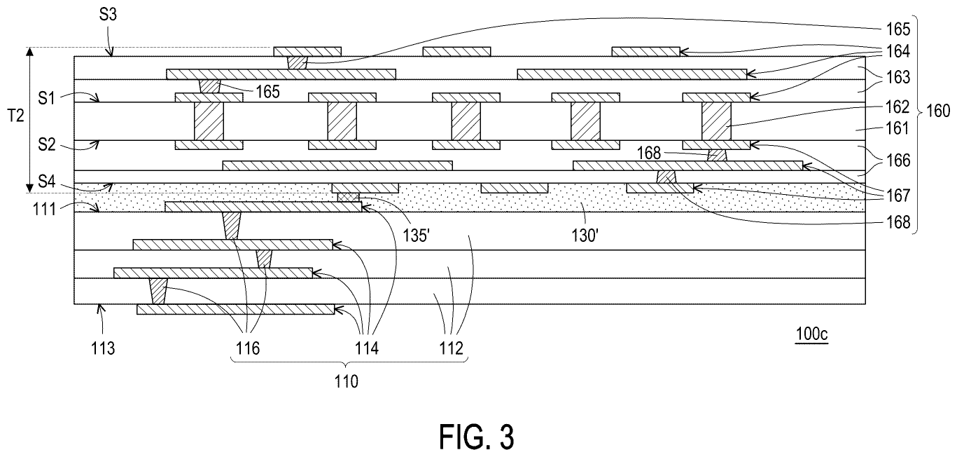

FIG. 3 is a schematic cross-sectional view of a substrate structure according to another embodiment of the disclosure. Please refer to FIG. 1 and FIG. 3 simultaneously. A substrate structure 100c of the embodiment is similar to the substrate structure 100a, but the main difference between the two is that the structural configuration of a first build-up structure layer 160 of the embodiment is different from the structural configuration of the first build-up structure layer 120.

Specifically, at least one second dielectric layer of the first build-up structure layer 160 includes an internal dielectric layer 161 and at least two external dielectric layers (four external dielectric layers 163 and 166 are schematically shown), wherein the internal dielectric layer 161 is located between the external dielectric layers 163 and 166. The internal dielectric layer 161 has an upper surface S1 and a lower surface S2 opposite to each other. The external dielectric layer 163 and the second conductive pattern layer 164 are alternately stacked on the upper surface S1, and the external dielectric layer 166 and the second conductive pattern layer 167 are alternately stacked on the lower surface S2. The materials of the internal dielectric layer 161 and the external dielectric layers 163 and 166 are, for example, organic materials, inorganic materials, or non-conductive composite materials. In an embodiment, the organic material is, for example, a glass fiber resin (for example, FR4), a prepreg (PP), or an inorganic filler mixed in a resin (for example, an Ajinomoto build-up film (ABF)), but not limited thereto. In an embodiment, the inorganic material is, for example, glass, ceramic, or glass ceramic. In an embodiment, the coefficient of thermal expansion of the inner dielectric layer 161 is different from the coefficients of thermal expansion of the two external dielectric layers 163 and 166. In an embodiment, the material of the internal dielectric layer 161 may be, for example, glass, and the materials of the external dielectric layers 163 and 166 may be, for example, prepregs (PP) or Ajinomoto build-up films (ABF), but not limited thereto.

Furthermore, the first build-up structure layer 160 has an outer surface S3 and an inner surface S4 opposite to each other and includes a conductive hole 162, a conductive hole 165, and a conductive hole 168. The conductive hole 162 is, for example, a conductive through hole, penetrates the internal dielectric layer 161, and electrically connects the second conductive pattern layer 164 located on the upper surface S1 and the second conductive pattern layer 167 located on the lower surface S2. The conductive hole 165 is, for example, a conductive blind hole, is located in the external dielectric layer 163, and electrically connects two adjacent second conductive pattern layers 164. The conductive hole 168 is, for example, a conductive blind hole, a conductive through hole, or a combination thereof, is located in the external dielectric layer 166, and electrically connects two adjacent second conductive pattern layers 167. In an embodiment, the second conductive pattern layer 164 and the second conductive pattern layer 167 may be redistribution circuit layers. In an embodiment, a thickness T2 of the first build-up structure layer 160 may be, for example, 100 μm to 1600 μm.

In addition, a bonding layer 130′ of the embodiment is located between the coreless substrate 110 and the first build-up structure layer 160, and covers the first surface 111 of the coreless substrate 110, the first conductive pattern layer 114 located on the first surface 111, the inner surface S4 of the first build-up structure layer 160, and the second conductive pattern layer 167 located on the inner surface S4. A conductive member 135′ is disposed in the bonding layer 130′ and electrically connects the first conductive pattern layer 114 located on the first surface 111 and the second conductive pattern layer 167 located on the inner surface S4.

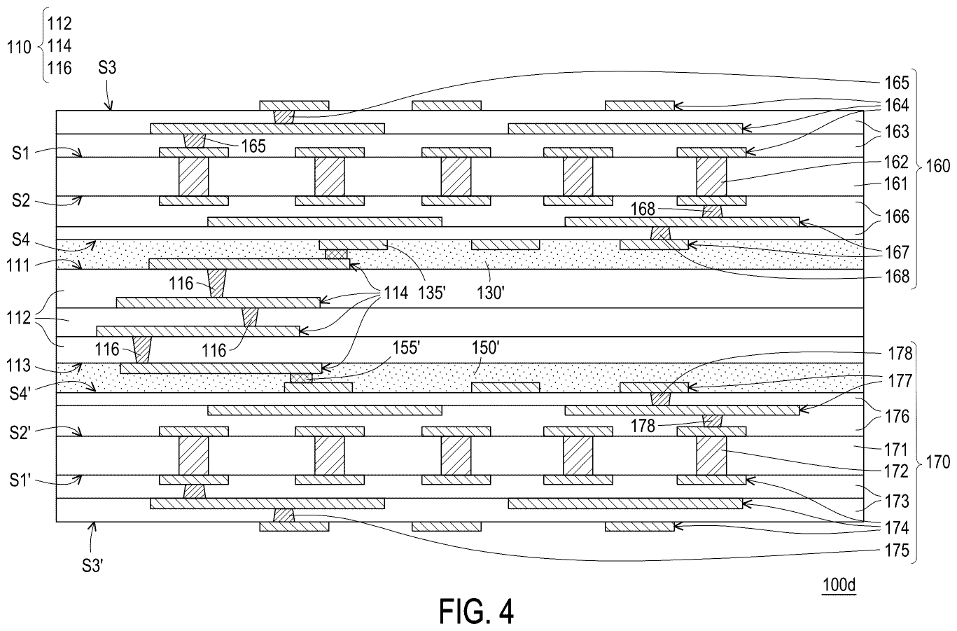

FIG. 4 is a schematic cross-sectional view of a substrate structure according to another embodiment of the disclosure. Please refer to FIG. 3 and FIG. 4 simultaneously. A substrate structure 100d of the embodiment is similar to the substrate structure 100c, but the main difference between the two is that in the embodiment, the substrate structure 100d also includes a second build-up structure layer 170 disposed on the coreless substrate 110 and including at least one third dielectric layer and at least one third conductive pattern layer (four third conductive pattern layers 174 and 177 are schematically shown). The coreless substrate 110 is located between the first build-up structure layer 160 and the second build-up structure layer 170. The coefficient of thermal expansion of the third dielectric layer is less than the coefficient of thermal expansion of the first dielectric layer 112, and the third conductive pattern layers 174 and 177 are electrically connected to the first conductive pattern layer 114.

Specifically, the at least one third dielectric layer of the second build-up structure layer 170 includes an internal dielectric layer 171 and at least two external dielectric layers (four external dielectric layers 173 and 176 are schematically shown), wherein the internal dielectric layer 171 is located between the external dielectric layers 173 and 176. The internal dielectric layer 171 has an upper surface S1′ and a lower surface S2′ opposite to each other. The external dielectric layer 173 and the third conductive pattern layer 174 are alternately stacked on the upper surface S1′, and the external dielectric layer 176 and the third conductive pattern layer 177 are alternately stacked on the lower surface S2′. The materials of the internal dielectric layer 171 and the external dielectric layers 173 and 176 are, for example, organic materials, inorganic materials, or non-conductive composite materials. In an embodiment, the organic material is, for example, a glass fiber resin (for example, FR4), a prepreg (PP), or an inorganic filler mixed in a resin (for example, an Ajinomoto build-up film (ABF)), but not limited thereto. In an embodiment, the inorganic material is, for example, glass, ceramic, or glass ceramic. In an embodiment, the coefficient of thermal expansion of the internal dielectric layer 171 is different from the coefficients of thermal expansion of the external dielectric layers 173 and 176. In an embodiment, the material of the internal dielectric layer 171 may be, for example, glass, and the materials of the external dielectric layers 173 and 176 may be, for example, prepregs (PP) or Ajinomoto build-up films (ABF), but not limited thereto.

Furthermore, the second build-up structure layer 170 has an outer surface S3′ and an inner surface S4′ opposite to each other and includes a conductive hole 172, a conductive hole 175, and a conductive hole 178. The conductive hole 172 is, for example, a conductive through hole, penetrates the internal dielectric layer 171, and electrically connects the third conductive pattern layer 174 located on the upper surface S1′ and the third conductive pattern layer 177 located on the lower surface S2′. The conductive hole 175 is, for example, a conductive blind hole, is located in the external dielectric layer 173, and electrically connects two adjacent third conductive pattern layers 174. The conductive hole 178 is, for example, a conductive blind hole, a conductive through hole, or a combination thereof, is located in the external dielectric layer 176, and electrically connects two adjacent third conductive pattern layers 177. In an embodiment, the third conductive pattern layer 174 and the third conductive pattern layer 177 may be redistribution circuit layers.

In addition, a bonding layer 150′ of the embodiment is located between the coreless substrate 110 and the second build-up structure layer 170, and covers the second surface 113 of the coreless substrate 110, the first conductive pattern layer 114 located on the second surface 113, the inner surface S4′ of the second build-up structure layer 170, and the third conductive pattern layer 177 located on the inner surface S4′. The conductive member 155′ is disposed in the bonding layer 150′ and electrically connects the first conductive pattern layer 114 located on the second surface 113 and the third conductive pattern layer 177 located on the inner surface S4′.

In summary, in the substrate structure of the disclosure, since the coefficient of thermal expansion of the second dielectric layer of the first build-up structure layer is less than the coefficient of thermal expansion of the first dielectric layer without the core substrate, the compressive stress may be formed to suppress the warping of the substrate structure, so that the substrate structure of the disclosure can have improved structural reliability.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. A substrate structure, comprising:
a coreless substrate, comprising at least one first dielectric layer and at least one first conductive pattern layer; and
a first build-up structure layer, disposed on the coreless substrate and comprising at least one second dielectric layer and at least one second conductive pattern layer, wherein a coefficient of thermal expansion of the at least one second dielectric layer is less than a coefficient of thermal expansion of the at least one first dielectric layer, and the at least one second conductive pattern layer is electrically connected to the at least one first conductive pattern layer.

2. The substrate structure according to claim 1, further comprising:
a bonding layer, disposed between the coreless substrate and the first build-up structure layer; and
at least one conductive member, disposed in the bonding layer and electrically connecting the at least one second conductive pattern layer and the at least one first conductive pattern layer.

3. The substrate structure according to claim 2, wherein a material of the at least one conductive member comprises conductive paste, metal paste, or nanowire.

4. The substrate structure according to claim 1, wherein a material of the at least one first dielectric layer of the coreless substrate comprises an organic material, an inorganic material, or a non-conductive composite material.

5. The substrate structure according to claim 1, wherein a material of the at least one second dielectric layer of the first build-up structure layer comprises an organic material, an inorganic material, or a non-conductive composite material.

6. The substrate structure according to claim 1, wherein a material of the at least one first dielectric layer of the coreless substrate and a material of the at least one second dielectric layer of the first build-up structure layer are the same.

7. The substrate structure according to claim 1, wherein a material of the at least one first dielectric layer of the coreless substrate is different from a material of the at least one second dielectric layer of the first build-up structure layer.

8. The substrate structure according to claim 1, further comprising:
a second build-up structure layer, disposed on the coreless substrate and comprising at least one third dielectric layer and at least one third conductive pattern layer, wherein the coreless substrate is located between the first build-up structure layer and the second build-up structure layer, wherein a coefficient of thermal expansion of the at least one third dielectric layer is less than a coefficient of thermal expansion of the at least one first dielectric layer, and the at least one third conductive pattern layer is electrically connected to the at least one first conductive pattern layer.

9. The substrate structure according to claim 8, wherein the coefficient of thermal expansion of the at least one third dielectric layer is different from the coefficient of thermal expansion of the at least one second dielectric layer.

10. The substrate structure according to claim 1, wherein the at least one second dielectric layer of the first build-up structure layer comprises an internal dielectric layer and at least two external dielectric layers, the internal dielectric layer is located between the at least two external dielectric layers, and a coefficient of thermal expansion of the internal dielectric layer is different from coefficients of thermal expansion of the at least two external dielectric layers.
